(19) United States
(12) Patent Application Publication
(10) Pub. No.: US 2008/0180873 A1
(43) Pub. Date: Jul. 31, 2008

(54) Securing a substrate to an electrostatic chuck

(75) Inventors: Wendell Glenn Boyd, Morgan Hill, CA (US); Roy Vincent Marsh, East Sussex (GB); Jonathon Yancey Simmons, San Jose, CA (US)

Correspondence Address: APPLIED MATERIALS, INC., P. O. BOX 450A, SANTA CLARA, CA, 95052, US

(73) Assignee: APPLIED MATERIALS, INC.

(21) Appl. No.: 11/700,253

(22) Filed: Jan. 31, 2007

(51) Int. Cl. H01L 21/683

(52) U.S. Cl. 361/234

(57) ABSTRACT

The present invention relates to securing a substrate to an electrostatic chuck to minimise damage to the substrate. In particular, the present invention relates to securing a substrate to an electrostatic chuck provided as part of a substrate scanner in an ion implanter. A method of loading a substrate on an electrostatic chuck of a substrate holder is provided that comprises placing a substrate onto the chuck; supplying a first voltage to an electrode in the chuck thereby causing an electrostatic force due to attraction of the substrate to the chuck; subsequently, but prior to moving the substrate, supplying a second voltage to the electrode greater than the first voltage thereby causing an increased electrostatic force.

### FIELD OF THE INVENTION

The present invention relates to securing a substrate to an electrostatic chuck to minimise damage to the substrate. In particular, the present invention relates to securing a substrate to an electrostatic chuck provided as part of a substrate scanner in an ion implanter.

### BACKGROUND OF THE INVENTION

Although the present invention is not limited to the field of ion implanters, this field corresponds to a contemplated application and provides a useful context for understanding the invention. Hence there follows a description of ion implanters.

Ion implanters are well known and generally conform to a common design as follows. An ion source produces a mixed beam of ions from a precursor gas or the like. Only ions of a particular species are usually required for implantation in a substrate, for example a particular dopant for implantation in a semiconductor wafer. The required ions are selected from the mixed ion beam using a mass-analysing magnet in association with a mass-resolving slit. Hence, an ion beam containing almost exclusively the required ion species emerges from the mass-resolving slit to be transported to a process chamber where the ion beam is incident on a substrate held in place in the ion beam path by a substrate holder.

Often, the cross-sectional profile of the ion beam is smaller than the substrate to be implanted. For example, the ion beam may be a ribbon beam smaller than the substrate in one axial direction or a spot beam smaller than the substrate in both axial directions. In order to ensure ion implantation across the whole of the substrate, the ion beam and substrate are moved relative to one another such that the ion beam scans the entire substrate surface. This may be achieved by (a) deflecting the ion beam to scan across the substrate that is held in a fixed position, (b) mechanically moving the substrate whilst keeping the ion beam path fixed or (c) a combination of deflecting the ion beam and moving the substrate. For a spot beam, relative motion is generally effected such that the ion beam traces a raster pattern on the substrate. To ensure good throughput of substrates through the ion implanter, the substrates are subjected to strong acceleration and deceleration forces as the substrate changes direction at the end of each scan line and as the substrate is stepped between scan lines.

Our U.S. Pat. No. 6,956,223 describes an ion implanter of the general design described above. A single wafer is held in a moveable substrate holder. While some steering of the ion beam is possible, the implanter is operated such that the ion beam follows a fixed path during implantation. Instead, the wafer holder is moved along two orthogonal axes to cause the ion beam to scan over the wafer following a raster pattern.

The substrate holder may be provided with an electrostatic chuck to which the substrate is secured. Typically, the electrostatic chuck will comprise an electrode embedded in an insulator. A substrate is placed on the chuck and a voltage is applied to the electrode. This induces an accumulation of charge in the substrate such that the substrate is secured to the chuck by electrostatic attraction. In an alternative arrangement, two electrodes are provided in the chuck and biased with opposite polarities. This bipolar arrangement has the advantage of not placing a net bias on the substrate and allows an overall reduction in the voltages applied. U.S. Pat. No. 5,606,485 provides further details of electrostatic chucks.

The voltage applied to the electrode(s) in the chuck must be enough for the electrostatic attraction to secure the substrate firmly in position, particularly when being scanned through the ion beam where shifts in position will be at the expense of uniformity in the implant.

In addition, gas cooling of the substrate may be employed that is typically effected by providing the chuck with channels that open to the face of the chuck that supports the substrate. Gas is circulated through these channels at pressure to provide cooling to the substrate. Hence, the electrostatic attraction must also be enough to overcome the pressure of the gas that will try to force the substrate away from the chuck.

The large force necessary to secure a substrate firmly in place on an electrostatic chuck when faced with the large accelerations experienced during scanning can damage the substrate. In particular, this is seen for semiconductor wafer processing where defects and other damage is sometimes seen in the silicon on the back face of silicon wafers. Clearly, such structural damage has adverse effects on the performance of the high-value semiconductor devices formed on the wafers.

### SUMMARY OF THE INVENTION

Against this background, and from a first aspect, the present invention resides in a method of loading a substrate on an electrostatic chuck of a substrate holder, comprising: placing a substrate onto the chuck; supplying a first voltage to an electrode in the chuck to establish and to maintain an electrostatic force due to attraction of the substrate to the chuck; and, subsequently, supplying a second voltage to the electrode greater than the first voltage to establish and to maintain an increased electrostatic force.

Preferably, the method comprises preferentially supplying the first voltage when the substrate is at rest. Then the substrate may be moved only when the second voltage is supplied to the electrode. So, the first voltage may be supplied predominantly when the substrate is at rest, only being increased to the second voltage when the substrate is to be moved. Advantageously, the first voltage may be sufficient to hold the substrate securely in place when the substrate is static but may not be sufficient to hold the substrate securely in place when the substrate is scanned.

Hence, damage to the substrate may be minimised by applying a decreased voltage whenever the substrate is not being moved. Put another way, an increased voltage is only applied when the substrate is being moved. Thus, the present invention can also be viewed as a method of securing a substrate to an electrostatic chuck of a substrate holder comprising (a) generally, when the substrate is at rest, providing a voltage to an electrode of the chuck sufficient to secure the substrate in place with the substrate at rest but not sufficient to hold the substrate in place were the substrate to be moved; (b) immediately prior to moving the substrate, providing an increased voltage to the electrode sufficient to secure the substrate in place when the substrate is moved; (c) maintaining the increased voltage while the substrate is being moved; and (d) immediately after the substrate has been moved, providing a voltage to the electrode sufficient to secure the substrate in place with the substrate at rest but not sufficient to hold the substrate in place were the substrate to be moved.

Optionally, the method further comprises supplying a coolant gas to the chuck thereby to cool the substrate, and then supplying the second voltage to the electrode.

The present invention also resides in a method of scanning a substrate through an ion beam in an ion implanter, comprising: placing a substrate onto an electrostatic chuck of the substrate scanner; supplying a first voltage to an electrode in the chuck to establish and to maintain an electrostatic force due to attraction of the substrate to the chuck; supplying a coolant gas to the chuck thereby to cool the substrate; supplying a second voltage to the electrode greater than the first voltage to establish and to maintain an increased electrostatic force; scanning the substrate through the ion beam; and decreasing the voltage supplied to the electrode.

As before, this method may follow the principle that the second voltage is applied whenever the substrate is being moved, and the first voltage is applied whenever the substrate is at rest save for the short periods immediately before and after movement when the voltage is being increased and decreased respectively.

Optionally, the method further comprises gradually decreasing the supply of coolant gas to the chuck while decreasing the voltage supplied to the chuck to ensure a supply of coolant gas to the chuck when the voltage supplied to the chuck reaches zero volts. The supply of coolant gas may be decreased in proportion to the decrease in voltage, or vice versa. Advantageously, by keeping a small supply of gas to the chuck, the consequent pressure of the gas on the chuck can be enough to overcome a tendency for the substrate to stick to the chuck, even in the absence of a voltage on the electrode, as a result of charge accumulation on the wafer.

The present invention also resides in a method of unloading a substrate from an electrostatic chuck holding the substrate in place by virtue of electrostatic attraction arising from a voltage placed on an electrode of the chuck, the chuck also being provided with a coolant gas that provides a pressure acting to force the substrate from the chuck, the method comprising decreasing the voltage placed on the electrode to zero volts while decreasing the supply of coolant gas such that the supply of coolant gas is maintained when the voltage reaches zero. Preferably, the method comprises ensuring a supply of coolant gas at zero volts that is sufficient to stop the substrate sticking to the chuck. The exact pressure required may be determined as a matter of trial and error.

The invention may also be used with bipolar electrostatic chucks having a pair of electrodes. In this instance, complementary voltages may be applied to the electrodes, i.e. voltages of equal magnitude but opposite polarity.

### BRIEF DESCRIPTION OF THE DRAWINGS

In order that the present invention may be better understood, a preferred embodiment will now be described with reference to the accompanying drawings, in which:

FIG. 1 is a schematic representation of an electrostatic chuck that may be used with the present invention;

FIG. 2 is a schematic representation of an ion implanter that may be used with the present invention;

FIG. 3 is a block diagram illustrating a method of implanting a wafer according to an embodiment of the present invention; and

FIG. 4 is a graph showing the pressure on the substrate as electrode voltage and gas pressure are varied during loading of a wafer on an electrostatic chuck.

### DETAILED DESCRIPTION OF THE INVENTION

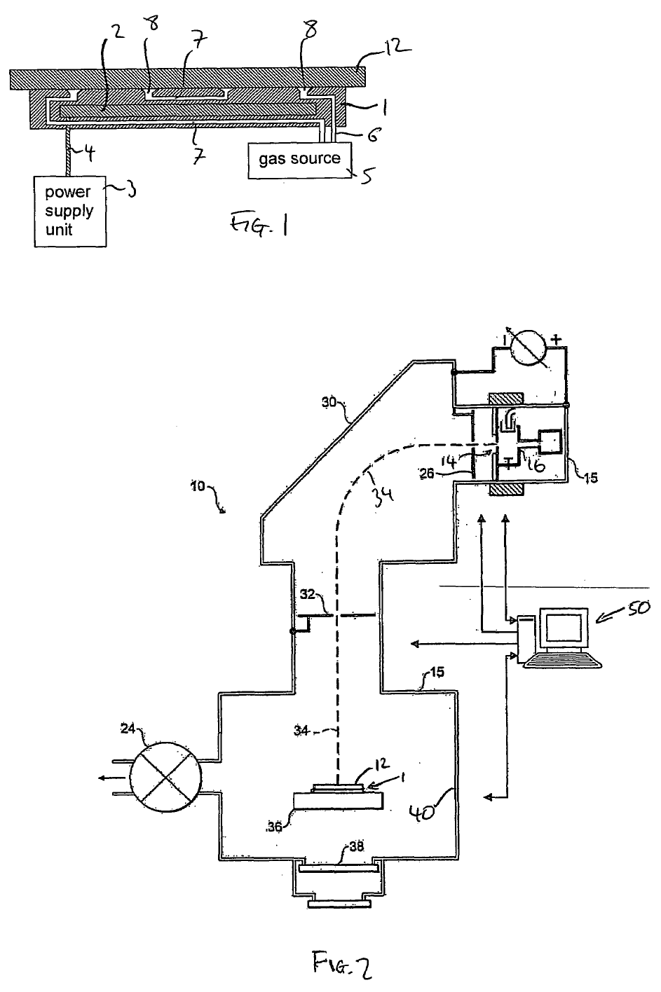

An electrostatic chuck 1 with which the present invention may be used is shown in FIG. 1. The chuck 1 is shown holding a silicon wafer 12 in place and may be mounted to any suitable substrate scanner, such as a cantilevered arm.

The chuck 1 comprises an insulating body, in which a a pair of electrodes 2 (only electrode is visible in the section of FIG. 1) are provided so as to be adjacent to the wafer 12. The electrodes 2 are connected to a power supply unit 3 by a cable 4 that provides positive and negative biases to the electrodes 2. The consequent charge accumulation in the adjacent back face of the wafer 12 results in an electrostatic attraction that urges the wafer 12 against the chuck 1. Supplying suitable voltages to the electrode 2 will see the wafer 12 held firmly in position.

The chuck 1 is also provided with a gas coolant system comprising a closed loop flowing to and from a pressurised gas source 5. The gas source 5 chills the gas as it circulates around the closed loop. The closed loop takes chilled gas to the chuck 1, circulates the chilled gas around the chuck 1 thereby to cool the wafer 12, and takes the warmed gas back to the gas source 5 to be chilled once more. As can be seen from FIG. 1, the closed loop comprises conduits 6 to take gas to and from the chuck 1, channels 7 provided in the chuck 1 for circulating the gas around the chuck 1, and outlets 8 that allow the chilled gas to contact the wafer 12 and hence remove heat through conduction.

As mentioned above, the present invention may find application in an ion implanter, although it is to be understood that the invention is not limited to such use. The following description of an ion implanter is not intended to be limiting, but will provide a useful context to aid in the understanding of the present invention.

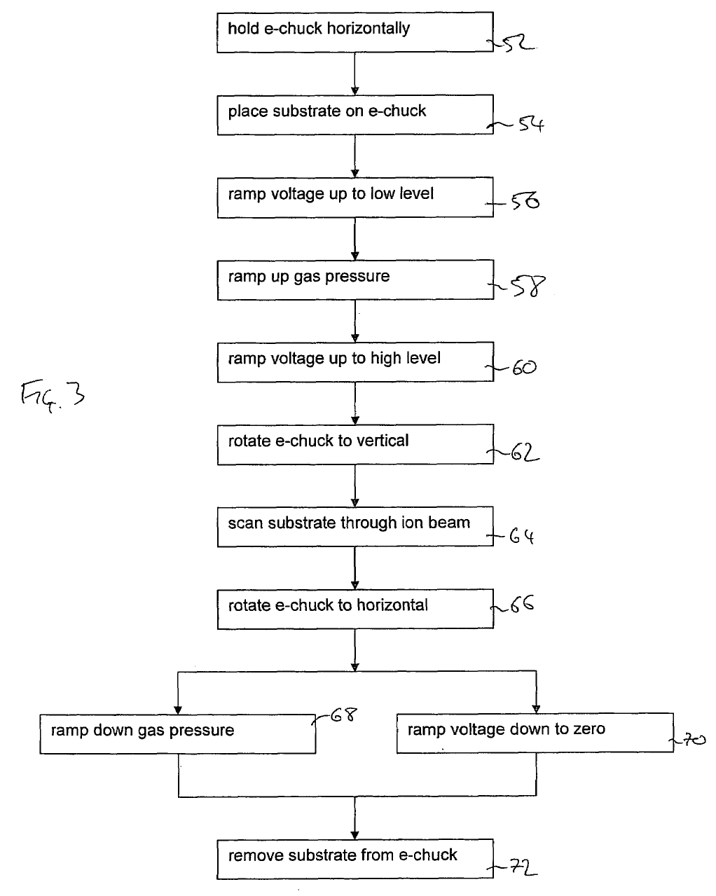

FIG. 2 shows a conventional ion implanter 10 for implanting ions in semiconductor wafers 12. The ion implanter 10 comprises a vacuum chamber 15 evacuated by pump 24. Ions are generated by an ion source 14 to be extracted and follow an ion path 34 that passes, in this embodiment, through a mass analysis stage 30. Ions of a desired mass are selected to pass through a mass-resolving slit 32 and then to strike the wafer 12. The ion source 14 generally comprises an arc chamber 16 containing a plasma for generating the desired ions.

Ions from within the arc chamber 16 are extracted using a negatively-biased (relative to ground) extraction electrode 26. The mixture of extracted ions are then passed through the mass analysis stage 30 so that they pass around a curved path under the influence of a magnetic field. The radius of curvature travelled by any ion is determined by its mass, charge state and energy, and the magnetic field is controlled so that, for a set beam energy, only those ions with a desired mass to charge ratio and energy exit along a path coincident with the mass-resolving slit 32. The emergent ion beam is then transported to the process chamber 40 where the target is located, i.e. the wafer 12 to be implanted or a beam stop 38 when there is no wafer 12 in the target position.

The semiconductor wafer 12 is mounted on an electrostatic chuck 1 of the wafer holder 36, wafers 12 being successively transferred to and from the wafer holder 36, for example through a load lock (not shown). The chuck 1 may correspond to the one shown in FIG. 1.

The ion implanter 10 operates under the management of a controller, such as a suitably programmed computer 50. The computer 50 controls scanning of the wafer 12 through the ion beam 34 to effect desired scanning patterns. These scanning patterns may comprise raster scans, including interlaced patterns, as is well known in the art.

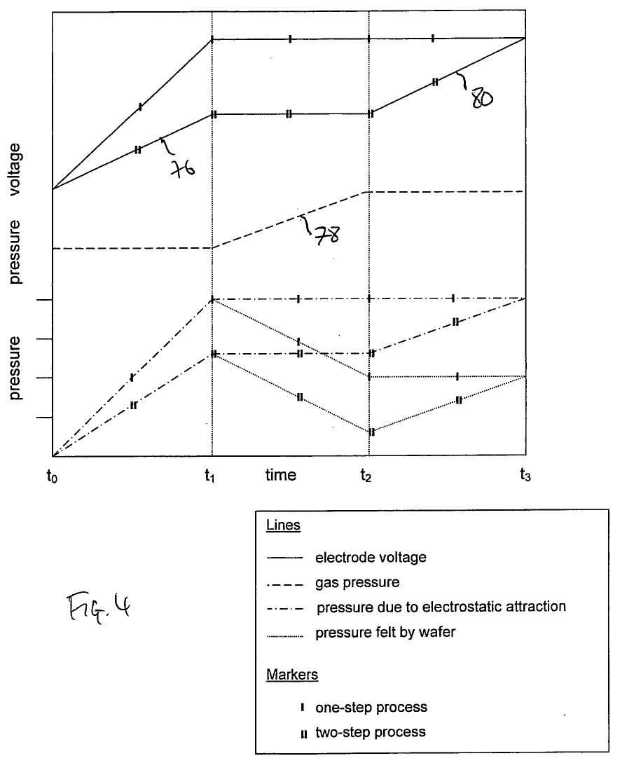

FIG. 3 presents a method of scanning a wafer 12 through an ion beam 34 using the ion implanter of FIG. 2, including loading the wafer 12 on an electrostatic chuck 1, in accordance with an embodiment of the present invention. This method may be implemented using the ion implanter 10 of FIG. 2, including the chuck 1 of FIG. 1. In particular, the method may be implemented by the controller 50. The method comprises a two-step process for loading the wafer 12 onto the chuck 1, as opposed to the conventional one-step process. To illustrate the advantages of the present invention, FIG. 4 shows the pressures felt by the wafer 12 during both one-step and two-step processes. A single vertical marker is used in FIG. 4 to denote the one-step process, whereas a double vertical marker is used to denote the two-step process.

At 52, the controller 50 issues instructions such that the wafer holder 36 is rotated to present the chuck 1 horizontally for accepting a wafer 12. At 54, the controller 50 controls a wafer-handling robot (not shown in FIG. 2) to load a wafer 12 onto the chuck 1. Once released, the wafer 12 is held on the chuck 1 by gravity. Guides or indicia may be provided on the chuck 1 to facilitate correct placement of the wafer 12 on the chuck 1. In the timeline of FIG. 4, the start point shown as to corresponds to completion of step 54, i.e. with the wafer 12 placed on the chuck 1.

At 56, the voltages applied to electrodes 2 is ramped up to a low level between times t₀ and t₁, as indicated at 76 in FIG. 4. This is the first part of a two-step process according to an embodiment of the present invention. FIG. 4 also shows the one-step process currently practiced. As can be seen, step 56 of the present invention sees the voltages on the chuck's electrodes 2 set to a lower level than for the one-step process. This leads to a reduced pressure being felt by the wafer 12 at time t₁ relative to the one-step process.

At 58, the gas pressure of the coolant gas is increased. As can be seen at 78 in FIG. 4 between times t₁ and t₂, the increase in gas pressure is similar for both the one-step and two-step processes. The voltages placed on the electrodes 2 are kept constant during this phase. Hence, in both processes, the pressure felt by the wafer 12 decreases as the gas pressure acts to force the wafer 12 away from the chuck 1. For the two-step process, the reduced voltage applied at 56 must be sufficient to keep the wafer 12 securely in place as the gas pressure is increased at 58.

At 60, the voltages applied to the electrodes 2 are increased for the two-step process as shown at 80 in FIG. 4 between t₂ and t₃. During this period, the voltages are kept constant in the one-step process. In fact, the voltages are increased in the two-step process to match that used in the one-step process at time t₃. Of course, the pressure felt by the wafer 12 in the two-step process increases as the voltages are increased. This increase is designed to allow the wafer 12 to be moved, i.e. the pressure felt by the wafer 12 between t₀ and t₃ is sufficient to keep the wafer 12 in place provided the wafer 12 is not moved, whereas at t₃ and beyond the pressure is sufficient to keep the wafer 12 in place even when moved through the ion beam 34.

As can be seen from FIG. 4, although the pressure felt by the wafer 12 is the same at t₃ whether the one-step or two-step process is followed, the pressures felt by the wafer 12 is lower at all times from t₀ through to t₃ for the two-step process. Hence, the wafer 12 is less likely to be damaged in this two-step loading process.

With the loading process complete, the chuck 1 is rotated at 62 so as to bring the wafer 12 to vertical ready for scanning. Scanning is then effected at 64 by moving the wafer 12 through the ion beam 34 to complete an implant according to the desired scan pattern. Once an implant is complete, the chuck 1 is rotated to the horizontal once more, as indicated at 66, so as to be ready for unloading the wafer 12. In order to minimise the pressure experienced by the wafer 12, the voltages on electrode 2 are ramped straight down to zero at 68. In addition, the gas pressure is ramped down concurrently at 70. These two steps are coordinated such that drop in gas pressure shadows the drop in voltage with the result that the slight pressure exerted by the gas on the wafer 12 stops the wafer 12 sticking to the chuck 1 (this effect is otherwise common because of residual charge accumulation such as from contaminants).

At 72, the wafer 12 is removed from the chuck 1 such that the chuck 1 is ready for another wafer 12 to be loaded.

As will be clear to the skilled person, variations may be made to the embodiments described above without departing from the scope of the invention as defined by the appended claims.

For example, the exact implementation to cause electrostatic attraction between the wafer 12 and chuck 1 is not critical. The present invention is equally well suited to work with single electrode chucks and bipolar electrode chucks.

FIG. 3 shows a processor where the voltages placed on the electrodes 2 are increased between t₀ and t₁ before the gas pressure is increased between t₁ and t₂. However, the voltages and the gas pressure may be increased concurrently, for example so that they increase proportionately. Thus, an end point will be reached where the coolant gas is supplied and the lower voltages are applied to the electrodes 2 such that the wafer 12 is held in position securely provided the wafer 12 is not moved. Then, at any time, the voltages applied to the electrodes 2 may be increased prior to the wafer 12 being moved.

The inclusion of a coolant gas supply is not necessary. Where gas cooling is not used, the same principle of applying a lesser voltage at times when the wafer 12 is not being moved may be used.

1. A method of loading a substrate on an electrostatic chuck of a substrate holder, comprising:
placing a substrate onto the chuck;
supplying a first voltage to an electrode in the chuck thereby to establish and to maintain an electrostatic force due to attraction of the substrate to the chuck; and,
subsequently, supplying a second voltage to the electrode greater than the first voltage thereby to establish and to maintain an increased electrostatic force.

2. The method of claim 1, comprising supplying the first voltage when the substrate is at rest.

3. The method of claim 2, comprising moving the substrate only when the second voltage is supplied to the electrode.

4. The method of claim 3, wherein the first voltage is sufficient to hold the substrate securely in place when the substrate is static but is not sufficient to hold the substrate securely in place when the substrate is scanned.

5. The method of claim 1, comprising gradually increasing the voltage supplied to the electrode to reach the first voltage.

6. The method of claim 1, further comprising supplying a coolant gas to the chuck thereby to cool the substrate, and then supplying the second voltage to the electrode.

7. The method of claim 6, comprising gradually increasing the voltage supplied to the electrode to reach the first voltage and gradually increasing the pressure of the coolant gas supplied to the chuck.

8. The method of claim 7, comprising increasing the voltage to reach the first voltage and then increasing the pressure of the coolant gas.

9. The method of claim 7, comprising increasing the voltage and the pressure of the coolant gas concurrently.

10. The method of claim 1, comprising gradually increasing the voltage supplied to the electrode to reach the second voltage.

11. A method of scanning a substrate through an ion beam in an ion implanter, comprising:
placing a substrate onto an electrostatic chuck of a substrate scanner;
supplying a first voltage to an electrode in the chuck thereby to establish and maintain an electrostatic force due to attraction of the substrate to the chuck;
supplying a coolant gas to the chuck thereby to cool the substrate;
supplying a second voltage to the electrode greater than the first voltage thereby to establish and maintain an increased electrostatic force;
scanning the substrate through the ion beam; and
decreasing the voltage supplied to the electrode.

12. The method of claim 11, further comprising gradually decreasing the supply of coolant gas to the chuck while decreasing the voltage supplied to the chuck.

13. The method of claim 12, comprising ensuring a supply of coolant gas to the chuck when the voltage supplied to the chuck reaches zero volts.

14. Amended) The method of claim 11, wherein supplying the first voltage to the electrode in the chuck further comprises supplying a complementary first voltage, being of the same magnitude but opposite polarity, to a further electrode in the chuck; and wherein supplying the second voltage to the electrode further comprises supplying a complementary second voltage, being of the same magnitude but opposite polarity, to the further electrode.

15. A method of unloading a substrate from an electrostatic chuck holding the substrate in place by virtue of electrostatic attraction arising from a voltage placed on an electrode of the chuck, the chuck also being provided with a coolant gas that provides a pressure acting to force the substrate from the chuck, the method comprising decreasing the voltage placed on the electrode to zero volts while decreasing the supply of coolant gas such that the supply of coolant gas is maintained when the voltage reaches zero.

16. The method of claim 15, comprising ensuring a supply of coolant gas at zero volts that is sufficient to stop the substrate sticking to the chuck.

17. The method of claim 16, wherein the substrate is held in place by virtue of complementary voltages placed on a pair of electrodes of the chuck, the method comprising decreasing the magnitude of the complementary voltages placed on the electrodes to zero volts.

18.-21. (canceled)

22. The method of claim 1, wherein supplying the first voltage to the electrode in the chuck further comprises supplying a complementary first voltage, being of the same magnitude but opposite polarity, to a further electrode in the chuck; and wherein supplying the second voltage to the electrode further comprises supplying a complementary second voltage, being of the same magnitude but opposite polarity, to the further electrode.
